(19) United States
(12) Patent Application Publication
(10) Pub. No.: US 2023/0392268 A1
(43) Pub. Date: Dec. 7, 2023

(54) Carbon Dioxide Reduction Device

(71) Applicant: Nippon Telegraph and Telephone Corporation, Tokyo (JP)

(72) Inventors: Akihiro Kono, Musashino-shi, Tokyo (JP); Yuya Uzumaki, Musashino-shi, Tokyo (JP); Sayumi Sato, Musashino-shi, Tokyo (JP); Takeshi Komatsu, Musashino-shi, Tokyo (JP)

(21) Appl. No.: 18/250,265

(22) PCT Filed: Nov. 17, 2020
(86) PCT No.: PCT/JP2020/042734

§ 371 Date: Apr. 24, 2023

(51) Int. Cl. C25B 3/26; C25B 1/01; C25B 9/19

(52) U.S. Cl. CPC C25B 3/26; C25B 1/01; C25B 9/19

(57) ABSTRACT

Included are an oxidation electrode that is formed in a film state on a transparent substrate and receives light from the outside, an oxidation bath that holds an electrolytic solution in which the oxidation electrode is immersed, a reduction electrode, a reduction bath that holds the electrolytic solution, in which the reduction electrode is immersed and which is subjected to bubbling with carbon dioxide from the outside, an electrolyte membrane that is disposed between the oxidation bath and the reduction bath and divides the electrolytic solution into an oxidation side and a reduction side, and a thermoelectric element including a heat absorbing plate that faces the transparent substrate, receives light transmitted through the transparent substrate, and converts the light into heat, including a heat radiation plate that faces the heat absorbing plate and radiates the heat of the heat absorbing plate, including thermoelectric materials interposed between the heat absorbing plate and the heat radiation plate.

### TECHNICAL FIELD

The present invention relates to a carbon dioxide reduction device.

### BACKGROUND ART

An increase in the concentration of carbon dioxide in the atmosphere is mentioned as a main cause of global warming. Reduction of carbon dioxide emissions has become a long-term challenge on a global scale. Meanwhile, energy supply relying on fossil fuels is to be reviewed in the medium and long term as an energy problem, and creation of a next-generation energy supply source is awaited.

As a way of suppressing emission of carbon dioxide and obtaining energy, technologies have been developed for utilizing unused energy such as exhaust heat, snow and ice heat, vibration, and electromagnetic waves and renewable energy such as sunlight. These power generation technologies enable only creation of electrical energy, and storage of energy is impossible with these technologies. Creation of chemical products using fossil fuels as raw materials is also impossible.

As a method of simultaneously solving these problems, a technique of reducing carbon dioxide using light energy has attracted attention. For example, Non Patent Literature 1 discloses a carbon dioxide reduction device by light irradiation. In the reduction device, when the oxidation electrode is irradiated with light, electron-hole pairs are generated and separated at the oxidation electrode, and oxygen and protons (H+) are generated by oxidation reaction of water. At the reduction electrode, a proton and an electron are bound to generate hydrogen, and a reduction reaction is caused. This reduction reaction generates carbon monoxide, formic acid, methane, and the like that can be used as energy resources.

Furthermore, for example, Non Patent Literature 2 discloses a carbon dioxide reduction device in which a solar cell is used to enhance the utilization efficiency of light energy.

### CITATION LIST

### Non Patent Literature

Non Patent Literature 1: Satoshi Yotsuhashi et al. “CO2Conversion with Light and Water by GaN Photo electroade”, Japanese Journal of Applied Physics, 51, 2012, p.02BP07-1-p.02BP07-3
Non Patent Literature 2: Qingxin Jia et al. “Direct Gas-phase CO2reduction for Solar Methane Generation Using a Gas Diffusion Electrode with a BiVO4:Mo and a Cu—In-e Photoanode”, Chem.Lett., 47, 2018, p.436-p.439

### SUMMARY OF INVENTION

### Technical Problem

However, in the conventional methods, the utilization efficiency of light energy is not sufficient. The oxidation electrode includes an optical semiconductor film, and the optical semiconductor film can absorb sunlight having a wavelength of, for example, 400 nm or less. The range of the wavelength of light that can be absorbed by the semiconductor film depends on the kind, the film thickness, and the like of the semiconductor material, and it is difficult for the optical semiconductor film (solar cell) to absorb all of the light energy. That is, the conventional carbon dioxide reduction devices have a problem of wasting light energy.

The present invention has been made in view of this problem, and an object of the present invention is to provide a carbon dioxide reduction device capable of utilizing light energy effectively over a wide wavelength range.

### Solution to Problem

A carbon dioxide reduction device according to an aspect of the present invention includes an oxidation electrode that is formed in a film state on a transparent substrate and receives light from outside, an oxidation bath that holds an electrolytic solution in which the oxidation electrode is immersed, a reduction electrode, a reduction bath that holds the electrolytic solution, in which the reduction electrode is immersed and which is subjected to bubbling with carbon dioxide from outside, an electrolyte membrane that is disposed between the oxidation bath and the reduction bath and divides the electrolytic solution into an oxidation side and a reduction side, and a thermoelectric element including a heat absorbing plate that faces the transparent substrate, receives light transmitted through the transparent substrate, and converts the light into heat, including a heat radiation plate that faces the heat absorbing plate and radiates the heat of the heat absorbing plate, including a thermoelectric material interposed between the heat absorbing plate and the heat radiation plate, including a high potential side connected to the oxidation electrode, and including a low potential side connected to the reduction electrode.

### Advantageous Effects of Invention

According to the present invention, it is possible to provide a carbon dioxide reduction device capable of utilizing light energy effectively over a wide wavelength range.

### BRIEF DESCRIPTION OF DRAWINGS

FIG. 1 is a schematic diagram illustrating a configuration example of a carbon dioxide reduction device according to a first embodiment of the present invention.

FIG. 2 is a schematic diagram illustrating a configuration example of a carbon dioxide reduction device according to a second embodiment of the present invention.

FIG. 3 is a schematic diagram illustrating a modified example of the solar cell illustrated in FIG. 2.

FIG. 4 is a schematic diagram illustrating a configuration example of a carbon dioxide reduction device according to a comparative example.

### DESCRIPTION OF EMBODIMENTS

Hereinafter, embodiments of the present invention will be described with reference to the drawings. The same reference signs are given to the same components in a plurality of drawings, and description thereof will not be repeated.

### First Embodiment

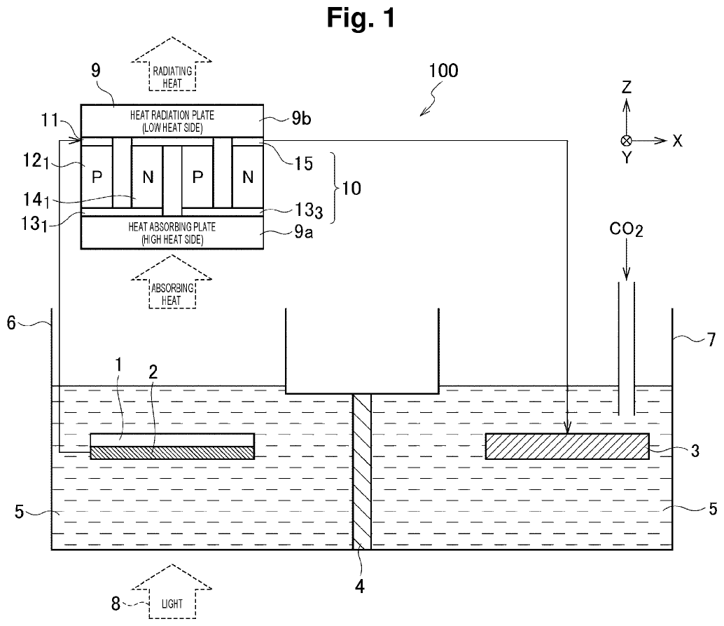

FIG. 1 is a schematic diagram illustrating a configuration example of a carbon dioxide reduction device according to a first embodiment of the present invention. In FIG. 1, the left-right direction is defined as the X direction, the direction toward the back side of the drawing is defined as the Y direction, and the direction toward the upper side of the drawing is defined as the Z direction.

A carbon dioxide reduction device 100 illustrated in FIG. 1 includes an oxidation electrode 2, an oxidation bath 6, a reduction electrode 3, a reduction bath 7, an electrolyte membrane 4, and a thermoelectric element 9. In the carbon dioxide reduction device 100, an oxidation-reduction reaction generates carbon monoxide, formic acid, methane, and the like that can be used as energy resources.

The oxidation electrode 2 is formed in a film state on a transparent substrate 1 and receives light 8 from the outside. The transparent substrate 1 is, for example, a sapphire substrate having a predetermined area on a plane in the XY direction. On the transparent substrate 1, for example, a compound that exhibits photoactivity or redox activity, such as a nitride semiconductor, titanium oxide, amorphous silicon, a ruthenium complex, or a cinium complex, is formed into a film on a plane, and thus the oxidation electrode 2 is formed.

The light 8 is, for example, sunlight. Note that the light 8 is not required to be sunlight. For example, the light source is a xenon lamp, a pseudo sunlight source, a halogen lamp, a mercury lamp, or a combination of these light sources.

The oxidation bath 6 holds an electrolytic solution 5 in which the oxidation electrode 2 is immersed. Examples of the electrolytic solution 5 include a potassium hydrogen carbonate aqueous solution, a sodium hydrogen carbonate aqueous solution, a potassium chloride aqueous solution, a sodium chloride aqueous solution, a potassium hydroxide aqueous solution, a rubidium hydroxide aqueous solution, and a cesium hydroxide aqueous solution. FIG. 1 illustrates an example in which the bottom of the oxidation bath 6 is irradiated with the light 8 in the Z direction.

The reduction electrode 3 is, for example, a porous body of copper, platinum, gold, silver, indium, palladium, gallium, nickel, tin, cadmium, or an alloy thereof. Alternatively, the reduction electrode 3 is a compound such as silver oxide, copper oxide, copper(II) oxide, nickel oxide, indium oxide, tin oxide, tungsten oxide, tungsten(VI) oxide, or copper oxide, or a porous metal complex having a metal ion and an anionic ligand. Similarly to the oxidation electrode 2, the reduction electrode 3 has a predetermined area on a plane in the XY direction. The reduction electrode 3 may be disposed so as to form a plane in the Y direction similarly to the electrolyte membrane 4 described below.

The reduction bath 7 holds the electrolytic solution 5, in which the reduction electrode 3 is immersed, subjected to bubbling with carbon dioxide from the outside. The electrolytic solution 5 is the same as the electrolytic solution 5 in the oxidation bath 6.

The electrolyte membrane 4 is disposed between the oxidation bath 6 and the reduction bath 7, and divides the electrolytic solution 5 into an oxidation side and a reduction side. The electrolyte membrane 4 is, for example, any one of Nafion (registered trademark), FORBLUE, and Aquivion that are an electrolyte membrane having a carbon-fluorine skeleton, or SELEMION, NEOSEPTA, or the like that is an electrolyte membrane having a carbon-hydrogen skeleton.

In the thermoelectric element 9, a heat absorbing plate 9a facing the transparent substrate 1 receives the light 8 transmitted through the transparent substrate 1 and converts the light 8 into heat, a heat radiation plate 9b facing the heat absorbing plate 9a with thermoelectric materials 12 and 14 interposed therebetween radiates the heat of the heat absorbing plate 9b, a high potential side is connected to the oxidation electrode 2, and a low potential side is connected to the reduction electrode 3.

As thermoelectric materials 9e and 9g, a conjugated conductive polymer is used that has a linear chain having a conjugated double bond, and in the conjugated conductive polymer, electrons move on the n bond. Examples of the conjugated conductive polymer include polythiophene, polyaniline, polyacetylene, polypyrrole, polycarbazolenevinylene, and poly(3,4-ethylenedioxythiophene). These conjugated conductive polymers are known to exhibit high thermoelectric conversion characteristics even in a temperature range of 100° C. or lower.

As illustrated in FIG. 1, the thermoelectric element 9 is configured by sandwiching a thermoelectric module 10 between the heat absorbing plate 9a and the heat radiation plate 9b. The heat absorbing plate 9a and the heat radiation plate 9b include, for example, a copper material, which has a relatively high thermal conductivity. The heat absorbing plate 9a receives light transmitted through the oxidation electrode 2 and the transparent substrate 1 and converts the light into heat. The heat generated in the heat absorbing plate 9a is radiated via the thermoelectric module 10 from the heat radiation plate 9b to the outside. The thermoelectric element 9 converts light having a wavelength of, for example, 400 nm or more transmitted through the transparent substrate 1 and the oxidation electrode 2 into heat.

In the thermoelectric element 9, the temperature difference ΔT (K), the potential difference ΔV (V), and the Seebeck coefficient α (V/K) as a performance index have a relation expressed by the following equation, and the temperature difference ΔT and the potential difference ΔV have a proportional relation.

Math.1

ΔV=α×ΔT (1)

The thermoelectric module 10 includes a positive electrode 11, p-type thermoelectric materials 121 and 122, common electrodes 131, 132, and 133, n-type thermoelectric materials 141 and 142, and a negative electrode 15. The heat absorbing plate 9a and each of the common electrodes 131 and 132 are insulated from each other by an insulating layer (not illustrated), and the heat radiation plate 9b and each electrode (the positive electrode 11, the common electrode 132, the negative electrode 15) are insulated from each other by an insulating layer (not illustrated).

In the p-type thermoelectric materials 121 and 122, holes serve as carriers to transfer the heat generated by conversion in the heat absorbing plate 9a to the heat radiation plate 9b. In the n-type thermoelectric materials 141 and 142, electrons serve as carriers to transfer the heat to the heat radiation plate 9b. Therefore, in FIG. 1, the voltage on the oxidation electrode 2 side is high, and the voltage on the reduction electrode 3 side is low. FIG. 1 illustrates an example in which the p-type and the n-type thermoelectric materials are stacked into only two layers, but the p-type and the n-type thermoelectric materials are actually stacked into multiple layers.

As described above, the carbon dioxide reduction device 100 according to the present embodiment includes the oxidation electrode 2 that is formed in a film state on the transparent substrate 1 and receives light from the outside, the oxidation bath 6 that holds the electrolytic solution 5 in which the oxidation electrode 2 is immersed, the reduction electrode 3, the reduction bath 7 that holds the electrolytic solution 5, in which the reduction electrode 3 is immersed, subjected to bubbling with carbon dioxide from the outside, the electrolyte membrane 4 that is disposed between the oxidation bath 6 and the reduction bath 7 and divides the electrolytic solution 5 into the oxidation side and the reduction side, and the thermoelectric element 9 including the heat absorbing plate 9a that faces the transparent substrate 1, receives light transmitted through the transparent substrate 1, and converts the light into heat, including the heat radiation plate 9b that faces the heat absorbing plate 9a and radiates the heat of the heat absorbing plate 9a, including the thermoelectric materials 12 and 14 interposed between the heat absorbing plate 9a and the heat radiation plate 9b, including the high potential side connected to the oxidation electrode 2, and including the low potential side connected to the reduction electrode 3. Thus, a carbon dioxide reduction device can be provided that is capable of utilizing light energy of, for example, sunlight effectively over a wide wavelength range.

### Second Embodiment

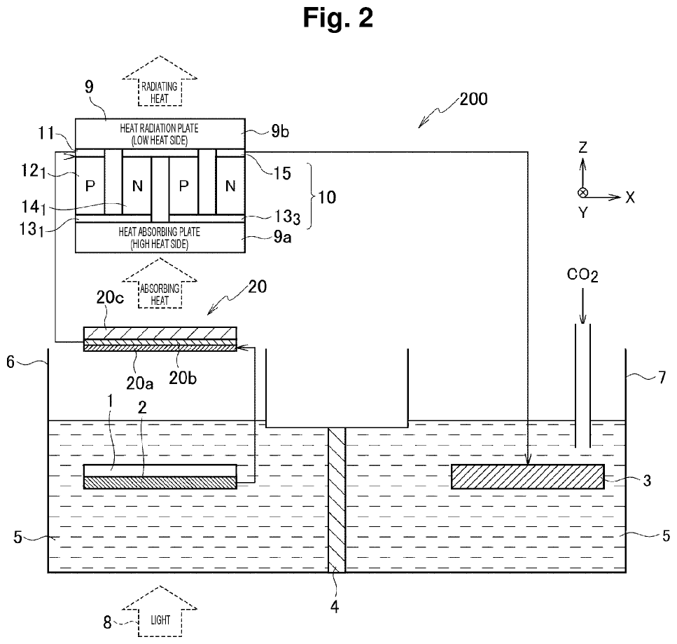

FIG. 2 is a schematic diagram illustrating a configuration example of a carbon dioxide reduction device according to a second embodiment of the present invention. A carbon dioxide reduction device 200 illustrated in FIG. 2 is different from the carbon dioxide reduction device 100 (FIG. 1) in that a solar cell 20 is included.

The solar cell 20 is disposed between a transparent substrate 1 and a heat absorbing plate 9a, and generates a voltage by light 8 transmitted through an oxidation electrode 2 and the transparent substrate 1. As the solar cell 20, any of a crystalline silicon solar cell, a single crystal silicon solar cell, a polycrystalline silicon solar cell, an amorphous silicon solar cell, a compound semiconductor solar cell, and a dye-sensitized solar cell can be used.

The solar cell 20 is configured by forming a cathode electrode 20a and an anode electrode 20b of the above materials in a film state on a transparent substrate 20c. The cathode electrode 20a is connected to the oxidation electrode 2, and the anode electrode 20b is connected to a negative electrode 11.

The cathode electrode 20a and the anode electrode 20b preferably have a narrower band gap than the oxidation electrode 2.

As described above, the carbon dioxide reduction device 200 according to the present embodiment includes the solar cell 20 in which the cathode electrode 20a is connected to the oxidation electrode 2 and the anode electrode 20b is connected to a thermoelectric element 9 (the negative electrode 11). Thus, a carbon dioxide reduction device can be provided that is capable of further utilizing light energy effectively over a wide wavelength range.

### Modified Example

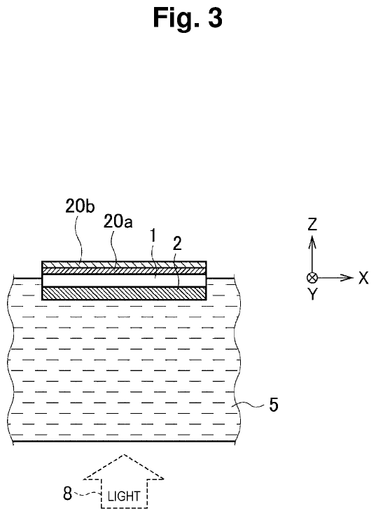

FIG. 3 is a schematic diagram illustrating a modified example of the solar cell 20 described in the second embodiment. As illustrated in FIG. 3, the solar cell 20 may be formed on the surface of a transparent substrate 1 opposite from an oxidation electrode 2. The solar cell 20 is exposed from the surface of an electrolytic solution 5.

As described above, the solar cell 20 of this modified example is formed on the surface of the transparent substrate 1, on which the oxidation electrode 2 is formed in a film state, opposite from the electrolytic solution 5, and the solar cell 20 is exposed from the surface of the electrolytic solution 5. Thus, a transparent substrate 20c is unnecessary, and the number of transparent substrates can be reduced to one (the transparent substrate 1), and as a result, the utilization efficiency of light energy can be enhanced.

### Experiment

Electrochemical measurement was performed in the above examples. Experimental conditions will be described.

An oxidation electrode 2 was configured by performing epitaxial growth of GaN as an n-type semiconductor and epitaxial growth of AlGaN in this order on a sapphire substrate, vacuum-depositing Ni on the AlGaN, and heat-treating the resulting product to form a promotor thin film of NiO. A transparent substrate and the oxidation electrode 2 were immersed in an electrolytic solution 5.

As the electrolytic solution 5, a 1.0 mol/L potassium hydroxide aqueous solution was used.

A copper plate was used as a reduction electrode 3. On the surface of the copper plate, a reduction reaction of carbon dioxide proceeds.

As an electrolyte membrane 4 that separates an oxidation bath 6 and a reduction bath 7, Nafion (registered trademark) was used.

A thermoelectric module 10 (FR-1S manufactured by Ferrotec Holdings Corporation) having an area of 10 cm² was used as a thermoelectric element 9.

As light 8, a 300 W xenon lamp was used instead of sunlight. A wavelength of 450 nm or more was cut with a filter, and the illuminance was set to 6.6 mW/cm². The area of the surface of the oxidation electrode 2 irradiated with the light 8 was set to 2.5 cm².

Bubbling with helium in the oxidation bath 6 and bubbling with carbon dioxide in the reduction bath 7 were each performed at a flow rate of 5 ml/min and a pressure of 0.18 MPa. The bubbling with helium was performed for the purpose of analyzing the reaction product. The helium and the carbon dioxide were sufficiently replaced, and irradiation with the light 8 was performed.

The current made to flow between the oxidation electrode 2 and the reduction electrode 3 by irradiation with the light 8 was measured with an electrochemical measurement device (potentiogalvanostat Model 1287 manufactured by Solartron Analytical).

Gases and liquids generated in the oxidation bath 6 and the reduction bath 7 were collected, and the reaction products were analyzed using a gas chromatograph, a liquid chromatograph, and a gas chromatograph mass spectrometer.

The Faraday efficiency of the carbon dioxide reduction reaction was calculated. The Faraday efficiency of carbon dioxide indicates the ratio of the number of electrons used in the carbon dioxide reduction reaction to the number of electrons moved between the oxidation electrode 2 and the reduction electrode 3 by light irradiation or voltage application.

$$\begin{matrix}Math . 2 & \\ Faraday efficiency = \frac{Number of electrons in reduction reaction}{Number of electrons moved between electrodes} & ( 2 )\end{matrix}$$

Here, the “number of electrons in reduction reaction” in the equation (2) is determined by converting the measured value of the integrated amount of the generated carbon dioxide reduction product into the number of electrons required for the production reaction. When the concentration of the reduction reaction product is represented by A (ppm), the flow rate of the carrier gas is represented by B (L/sec), the number of electrons required for the reduction reaction is represented by Z (mol), the Faraday constant is represented by F (C/mol), the volume of the model body of the gas is represented by Vₘ (L/mol), and the light irradiation or voltage application time is represented by T (sec), the “number of electrons in reduction reaction” can be calculated with the following equation.

$$\begin{matrix}Math . 3 & \\ Number of electrons in reduction reaction ( C ) = \frac{( A \times B \times Z \times F \times T \times {10}^{- 6} )}{{V}_{m}} & ( 3 )\end{matrix}$$

### Experiment 1

In Experiment 1, the Faraday efficiency of the carbon dioxide reduction reaction was determined in the configuration of the first embodiment (FIG. 1).

As the light 8, light having an illuminance of 6.6 mW/cm² from a 300 W high pressure xenon lamp (a wavelength of 450 nm or more is cut with a filter) was used for the purpose of obtaining light that can be easily quantified. Then, the oxidation electrode 2 was disposed so that the surface of the oxidation electrode 2 was irradiated with the light 8.

The heat absorbed by the heat absorbing plate 9a was simulated by a hot plate and applied. The temperature of the heat radiation plate 9b was set to 25° C., and temperature gradients of 5° C., 10° C., and 15° C. were generated.

### Experiment 2

Experiment 2 was performed in the configuration of the second embodiment (FIG. 2) in the same manner as Experiment 1.

As the solar cell 20, a single-cell single crystal amorphous silicon solar cell having an area of 2.5 cm and a voltage of 0.6 V was used. Experiment 2 was performed only at a temperature gradient of 5° C.

### Comparative Example

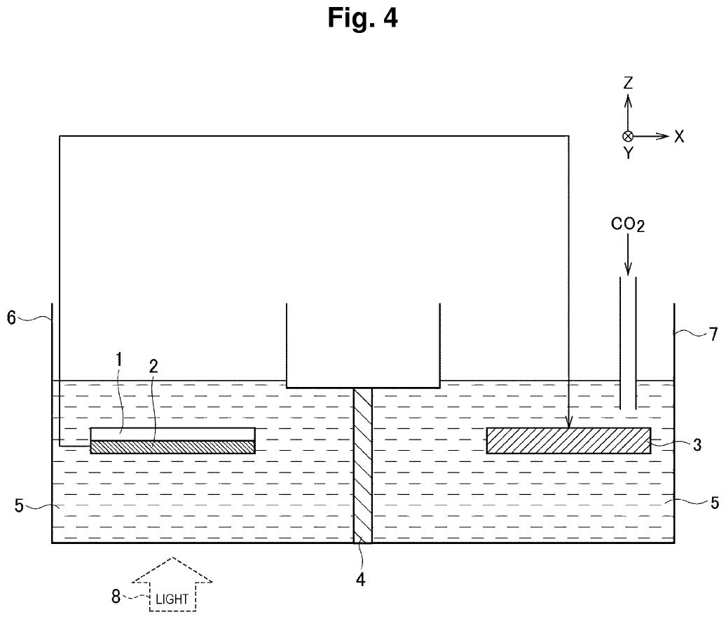

FIG. 4 illustrates a configuration of a carbon dioxide reduction device of a comparative example. As illustrated in FIG. 4, a thermoelectric element 9 and a solar cell 20 are not included in the configuration in the comparative example. Therefore, the heat absorbing plate 9a is not heated with a hot plate.

Table 1 shows the experimental results.

TABLE 1

| | Temperature | Voltage of | Faraday |
|---|---|---|---|
| | gradient | thermoelectric | efficiency |
| | (° C.) | element (V) | (%) |
| Experiment 1 | 5 | 0.3 | 40 |
| | 10 | 0.6 | 53 |
| | 15 | 0.9 | 65 |
| Experiment 2 | 5 | 0.3 | 64 |
| Comparative Example | — | — | 5 |

The Faraday efficiency at a temperature gradient of 5° C. in Experiment 2 is improved by 24% as compared with Experiment 1. This is because the reduction electrode 3 was biased to a low voltage due to the voltage of 0.6 V of the solar cell 20.

Furthermore, as indicated by the results at temperature gradients of 10° C. and 15° C. in Experiment 1, it has been confirmed that increasing the temperature difference in the thermoelectric element 9 improves the Faraday efficiency. This is considered to be because the increase in the bias voltage of the reduction electrode 3 caused the increase in the amount of the generated carbon monoxide and the increase in the amount of the generated formic acid and methane.

As described above, according to the carbon dioxide reduction devices 100 and 200 of the present embodiments, the efficiency of the carbon dioxide reduction reaction can be improved by using the thermal energy of light. In the above experiments, the light 8 was generated with a xenon lamp for the purpose of quantitatively controlling the temperature of the temperature gradient, but the temperature gradient is easy to generate using sunlight in the thermoelectric element 9.

As described above, the carbon dioxide reduction device 100 according to the present embodiment includes the oxidation electrode 2 that is formed in a film state on the transparent substrate 1 and receives light 8 from the outside, the oxidation bath 6 that holds the electrolytic solution 5 in which the oxidation electrode 2 is immersed, the reduction electrode 3, the reduction bath 7 that holds the electrolytic solution 5, in which the reduction electrode 3 is immersed, subjected to bubbling with carbon dioxide from the outside, the electrolyte membrane 4 that is disposed between the oxidation bath 6 and the reduction bath 7 and divides the electrolytic solution 5 into the oxidation side and the reduction side, and the thermoelectric element 9 including the heat absorbing plate 9a that faces the transparent substrate 1, receives light 8 transmitted through the transparent substrate 1, and converts the light 8 into heat, including the heat radiation plate 9b that faces the heat absorbing plate 9a and radiates the heat of the heat absorbing plate 9a, including the thermoelectric materials 12 and 14 interposed between the heat absorbing plate 9a and the heat radiation plate 9b, including the high potential side connected to the oxidation electrode 2, and including the low potential side connected to the reduction electrode 3. Thus, a carbon dioxide reduction device can be provided that is capable of utilizing light energy effectively over a wide wavelength range.

The present invention is not limited to the above-described embodiments, and modifications can be made within the scope of the gist of the present invention. For example, an example is shown in which the heat radiation plate 9b has a plate shape, but the present invention is not limited to this example. The heat radiation plate 9b may have a shape such that a cooling fin is included. The heat of the heat radiation plate 9b may be radiated to a natural water flow or the underground.

An example is shown in which the thermoelectric element 9 obtains the thermal energy from the light 8, but thermal energy to be wasted may be used. For example, exhaust heat of a boiler or a heat exchanger in a factory or the like may be used.

Thus, it is needless to say that the present invention includes various embodiments and the like not described herein. Therefore, the technical scope of the present invention is defined only by matters to specify the invention according to the scope of claims pertinent based on the foregoing description.

### INDUSTRIAL APPLICABILITY

The present invention can be widely used in the field related to the recycling of carbon dioxide.

### REFERENCE SIGNS LIST

1 Transparent substrate
2 Oxidation electrode
3 Reduction electrode
4 Electrolyte membrane
5 Electrolytic solution
6 Oxidation bath
7 Reduction bath
8 Light
9 Thermoelectric element
9a Heat absorbing plate
9b Heat radiation plate
10 Thermoelectric module
11 Positive electrode
12 p-Type thermoelectric material
13 Common electrode
14 n-Type thermoelectric material
15 Negative electrode
20 Solar cell
20a Cathode electrode
20b Anode electrode

1. A carbon dioxide reduction device comprising:
an oxidation electrode that is formed in a film state on a transparent substrate and receives light from outside;
an oxidation bath that holds an electrolytic solution in which the oxidation electrode is immersed;
a reduction electrode;
a reduction bath that holds the electrolytic solution in which the reduction electrode is immersed, the electrolytic solution being subjected to bubbling with carbon dioxide from outside;
an electrolyte membrane that is disposed between the oxidation bath and the reduction bath and divides the electrolytic solution into an oxidation side and a reduction side; and
a thermoelectric element including
a heat absorbing plate that faces the transparent substrate, receives light transmitted through the transparent substrate, and converts the light into heat,
a heat radiation plate that faces the heat absorbing plate and radiates the heat of the heat absorbing plate,
a thermoelectric material interposed between the heat absorbing plate and the heat radiation plate,
a high potential side connected to the oxidation electrode, and
a low potential side connected to the reduction electrode.

2. The carbon dioxide reduction device according to claim 1, further comprising a solar cell including a cathode electrode connected to the oxidation electrode and including an anode electrode connected to the thermoelectric element.

3. The carbon dioxide reduction device according to claim 2, wherein
the solar cell is formed on a surface of the transparent substrate on which the oxidation electrode is formed in a film state, the surface being opposite from the electrolytic solution, and the solar cell is exposed from a surface of the electrolytic solution.
